(19) United States
(12) Patent Application Publication
(10) Pub. No.: US 2024/0316630 A1
(43) Pub. Date: Sep. 26, 2024

(54) Additive Manufacturing Powder, Method For Producing Additive Manufacturing Powder, And Additively Manufactured Body

(71) Applicant: SEIKO EPSON CORPORATION, Tokyo (JP)

(72) Inventor: Yasutaka MATSUMOTO, Suwa (JP)

(21) Appl. No.: 18/612,197

(22) Filed: Mar. 21, 2024

(30) Foreign Application Priority Data
Mar. 22, 2023 (JP) 2023-045060

(51) Int. Cl. B22F 1/16; B22F 1/05; B22F 1/102; B22F 1/103; B22F 1/142; B22F 1/145; B33Y 70/00; C23C 16/40; C23C 16/44; C23C 16/455

(52) U.S. Cl. CPC B22F 1/16; B22F 1/05; B22F 1/102; B22F 1/103; B22F 1/142; B22F 1/145; B33Y 70/00; C23C 16/401; C23C 16/4417; C23C 16/45555; B22F 2301/35; B22F 2302/25; B22F 2304/10; B22F 2998/10

(57) ABSTRACT

An additive manufacturing powder used for producing an additively manufactured body to be formed into a metal sintered body by sintering includes: a modeling particle containing a metal material; and a coating film provided at a surface of the modeling particle and containing a compound derived from a coupling agent containing a hydrophobic functional group. When elemental analysis by X-ray photoelectron spectroscopy (XPS) is performed on the surface of the modeling particle, a Si content is 15 atomic % or more and 40 atomic % or less.

The present application is based on, and claims priority from JP Application Serial Number 2023-045060, filed on Mar. 22, 2023, the disclosure of which is hereby incorporated by reference herein in its entirety.

### BACKGROUND

### 1. Technical Field

The present disclosure relates to an additive manufacturing powder, a method for producing an additive manufacturing powder, and an additively manufactured body.

### 2. Related Art

As a technique for modeling a three-dimensional object, an additive manufacturing method using a metal powder is widely used in recent years. The technique is a technique of modeling a three-dimensional object and includes: a step of calculating a cross-sectional shape of a three-dimensional object when the three-dimensional object is thinly sliced in a plane perpendicular to a stacking direction; a step of forming a powder layer by layering a metal powder; and a step of bonding a portion of the powder layer based on the shape obtained by the calculation, in which the step of forming the powder layer and the step of bonding the portion are repeated.

As the additive manufacturing method, fused deposition modeling (FDM), selective laser sintering (SLS), a binder jet method, and the like are known according to a principle of bonding.

JP-A-2022-122503 discloses an additive manufacturing powder used for forming an additively manufactured body by a binder jetting method (binder jet method), the additive manufacturing powder containing a metal powder and a coating film that is provided at a particle surface of the metal powder and that contains a compound derived from a coupling agent containing a functional group. JP-A-2022-122503 also discloses that the additive manufacturing powder has an average particle diameter of 3.0 μm or more and 30.0 μm or less, and that the functional group contains a cyclic structure-containing group, a fluoroalkyl group, or a fluoroaryl group.

JP-A-2022-122503 discloses that, according to the above-described configuration, a reusable additive manufacturing powder is obtained even when the metal powder is heated under a heating condition of 200° C. for 24 hours.

JP-A-2022-122503 is an example of the related art.

### SUMMARY

However, in the binder jet method, it is difficult to strictly manage the number of times of reuse of the additive manufacturing powder. Specifically, there are particles that are reused only once user for modeling, and other particles that are reused several times. Depending on a size, a shape, and the like of an additively manufactured body to be produced, an amount of reused particles increases, and as a result, particles that are reused a number of times are generated. As the number of times of reuse increases, there is a concern that the coating film provided at the surface of each particle deteriorates and fluidity of the additive manufacturing powder decreases. The additive manufacturing powder disclosed in JP-A-2022-122503 has room for improvement in stability of the coating film, specifically, heat resistance of the coating film when the number of times of reuse increases.

Therefore, it is a problem to obtain an additive manufacturing powder having favorable heat resistance even when repeatedly subjected to a heat treatment.

An additive manufacturing powder according to an application example of the present disclosure is an additive manufacturing powder used for producing an additively manufactured body to be formed into a metal sintered body by sintering, the additive manufacturing powder including:
a modeling particle containing a metal material; and
a coating film provided at a surface of the modeling particle and containing a compound derived from a coupling agent containing a hydrophobic functional group, in which
when elemental analysis by X-ray photoelectron spectroscopy (XPS) is performed on the surface of the modeling particle, a Si content is 15 atomic % or more and 40 atomic % or less.

A method for producing an additive manufacturing powder according to an application example of the present disclosure is a method for producing an additive manufacturing powder used for producing an additively manufactured body to be formed into a metal sintered body by sintering, the method including:
reacting a coupling agent containing a hydrophobic functional group with a surface of a modeling particle containing a metal material to form a coating film containing a compound derived from the coupling agent, in which
when elemental analysis by X-ray photoelectron spectroscopy (XPS) is performed on the surface of the modeling particle, a Si content is 15 atomic % or more and 40 atomic % or less.

An additively manufactured body according to an application example of the present disclosure includes:
the additive manufacturing powder according to the application example of the present disclosure; and
a binder that binds particles of the additive manufacturing powder.

### BRIEF DESCRIPTION OF THE DRAWINGS

FIG. 1 is a process diagram showing a method for producing an additively manufactured body.

FIG. 2 shows the method for producing an additively manufactured body shown in FIG. 1.

FIG. 3 shows the method for producing an additively manufactured body shown in FIG. 1.

FIG. 4 shows the method for producing an additively manufactured body shown in FIG. 1.

FIG. 5 shows the method for producing an additively manufactured body shown in FIG. 1.

FIG. 6 shows the method for producing an additively manufactured body shown in FIG. 1.

FIG. 7 shows the method for producing an additively manufactured body shown in FIG. 1.

FIG. 8 shows the method for producing an additively manufactured body shown in FIG. 1.

FIG. 9 shows the method for producing an additively manufactured body shown in FIG. 1.

FIG. 10 shows the method for producing an additively manufactured body shown in FIG. 1.

FIG. 11 is a cross-sectional view schematically showing an additive manufacturing powder according to an embodiment.

FIG. 12 is a process diagram showing a configuration of a method for producing the additive manufacturing powder according to the embodiment.

### DESCRIPTION OF EMBODIMENTS

Hereinafter, a preferred embodiment of an additive manufacturing powder, a method for producing an additive manufacturing powder, and an additively manufactured body in the present disclosure will be described in detail with reference to the accompanying drawings.

### 1. Method for Producing Additively Manufactured Body

First, a method for producing an additively manufactured body using an additive manufacturing powder will be described.

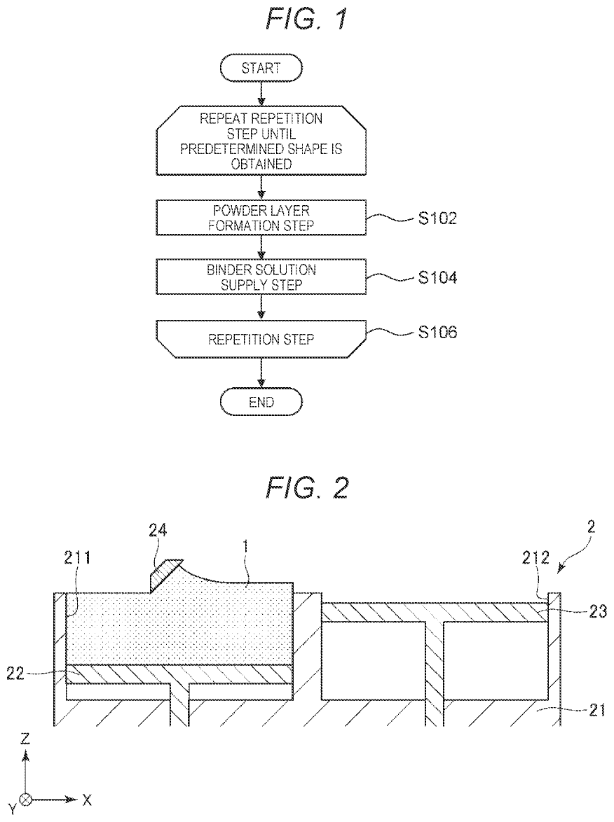

FIG. 1 is a process diagram showing the method for producing an additively manufactured body. FIGS. 2 to 10 show the method for producing an additively manufactured body shown in FIG. 1. In FIGS. 2 to 10, three axes orthogonal to each other are set as an X-axis, a Y-axis, and a Z-axis. Each axis is indicated by an arrow, and a tip side thereof is referred to as a “plus side” whereas a base side thereof is referred to as a “minus side”. In the following description, in particular, a plus side of the Z-axis is referred to as “upper”, and a minus side of the Z-axis is referred to as “lower”. Both directions parallel to the X-axis are referred to as an X-axis direction, both directions parallel to the Y-axis are referred to as a Y-axis direction, and both directions parallel to the Z-axis are referred to as a Z-axis direction.

The method for producing an additively manufactured body shown in FIGS. 1 to 10 is a method called a binder jet method, which is a type of an additive manufacturing method, and includes a powder layer formation step S102, a binder solution supply step S104, and a repetition step S106 as shown in FIG. 1. The binder jet method does not need any support structure for supporting a modeled object, and thus has an advantage that an additively manufactured body having a complicated shape can be produced.

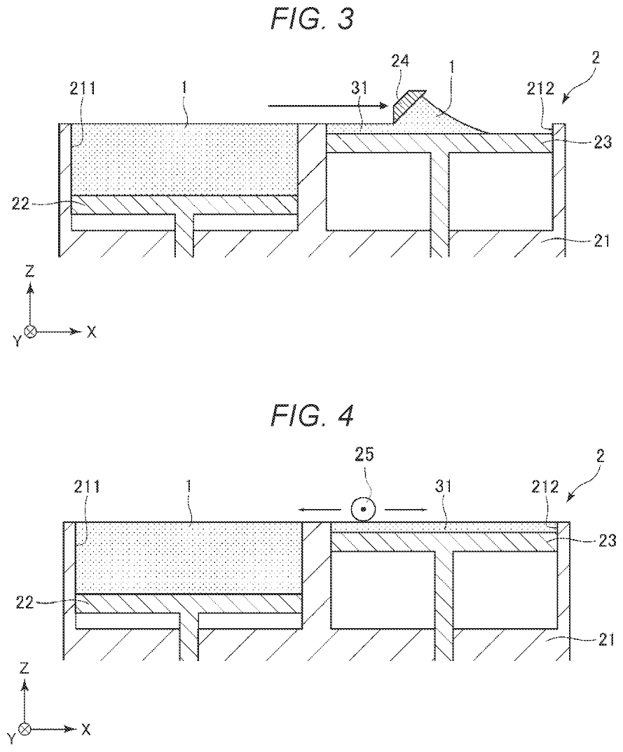

In the powder layer formation step S102, as shown in FIG. 3, an additive manufacturing powder 1 is spread to form a powder layer 31. In the binder solution supply step S104, a binder solution 4 is supplied to a predetermined area of the powder layer 31 to bind particles in the powder layer 31 to each other and obtain a binding layer 41. In the repetition step S106, the powder layer formation step S102 and the binder solution supply step S104 are repeated once or more to obtain an additively manufactured body 6 shown in FIG. 10. Hereinafter, the steps will be sequentially described.

The produced additively manufactured body 6 is subjected to a sintering treatment to form a metal sintered body. Since a shape of the additively manufactured body is reflected in the obtained metal sintered body, a metal sintered body having a complicated shape can be efficiently produced.

### 1.1. Additive Manufacturing Apparatus

First, before describing the powder layer formation step S102, an additive manufacturing apparatus 2 will be described.

The additive manufacturing apparatus 2 includes an apparatus main body 21, which includes a powder storage unit 211 and a modeling unit 212, a powder supply elevator 22 provided in the powder storage unit 211, a modeling stage 23 provided in the modeling unit 212, and a coater 24, a roller 25, and a liquid supply unit 26, which are movably provided on the apparatus main body 21.

The powder storage unit 211 is a recess that is provided in the apparatus main body 21 and whose upper portion is open. The additive manufacturing powder 1 is stored in the powder storage unit 211. An appropriate amount of the additive manufacturing powder 1 stored in the powder storage unit 211 is supplied to the modeling unit 212 by the coater 24.

The powder supply elevator 22 is disposed at a bottom portion of the powder storage unit 211. The powder supply elevator 22 is movable in an upper-lower direction in a state in which the additive manufacturing powder 1 is placed thereon. By moving the powder supply elevator 22 upward, the additive manufacturing powder 1 placed on the powder supply elevator 22 is pushed up and protruded from the powder storage unit 211. Accordingly, a protruded part of the additive manufacturing powder 1 can be moved toward the modeling unit 212.

The modeling unit 212 is a recess that is provided in the apparatus main body 21 and whose upper portion is open. The modeling stage 23 is disposed inside the modeling unit 212. On the modeling stage 23, the additive manufacturing powder 1 is spread in a layered shape by the coater 24. The modeling stage 23 is movable in the upper-lower direction in a state in which the additive manufacturing powder 1 is spread thereon. By appropriately setting a height of the modeling stage 23, an amount of the additive manufacturing powder 1 spread on the modeling stage 23 can be adjusted.

The coater 24 and the roller 25 are movable in the X-axis direction from the powder storage unit 211 to the modeling unit 212. By dragging the additive manufacturing powder 1, the coater 24 can uniformly distribute and spread the additive manufacturing powder 1 in a layered shape. The roller 25 compresses the uniformly distributed additive manufacturing powder 1 from above.

The liquid supply unit 26 is implemented by, for example, an ink jet head and a dispenser, and is movable in the X-axis direction and the Y-axis direction in the modeling unit 212. The liquid supply unit 26 can supply an intended amount of the binder solution 4 to an intended position. The liquid supply unit 26 may include a plurality of discharge nozzles in one head. The binder solution 4 may be discharged simultaneously or with a time difference from the plurality of discharge nozzles.

### 1.2. Powder Layer Formation Step

Next, the powder layer formation step S102 using the additive manufacturing apparatus 2 will be described. In the powder layer formation step S102, the additive manufacturing powder 1 is spread on the modeling stage 23 to form the powder layer 31. Specifically, as shown in FIGS. 2 and 3, using the coater 24, the additive manufacturing powder 1 stored in the powder storage unit 211 is dragged onto and uniformly distributed on the modeling stage 23 to have a uniform thickness. Accordingly, the powder layer 31 shown in FIG. 4 is obtained. At this time, a thickness of the powder layer 31 can be adjusted by lowering an upper surface of the modeling stage 23 below an upper end of the modeling unit 212 and adjusting a lowering amount.

Next, as shown in FIG. 4, the roller 25 is moved in the X-axis direction while compressing the powder layer 31 in a thickness direction by the roller 25. Accordingly, a filling rate of the additive manufacturing powder 1 in the powder layer 31 can be increased. The compression by the roller 25 may be performed as necessary, and may be omitted. The powder layer 31 may be compressed by a unit different from the roller 25, for example, by a pressing plate.

### 1.3. Binder Solution Supply Step

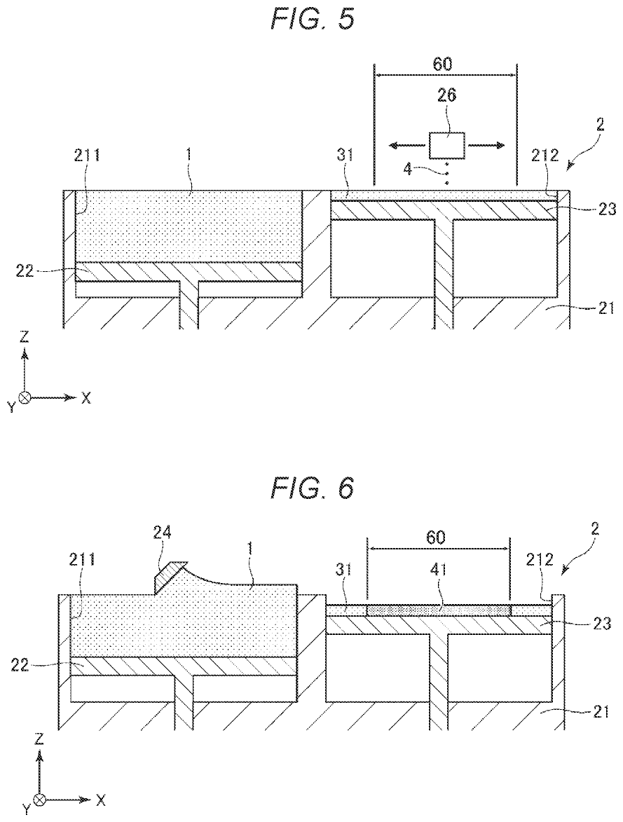

In the binder solution supply step S104, as shown in FIG. 5, the liquid supply unit 26 supplies the binder solution 4 to a formation area 60 of the powder layer 31 corresponding to the additively manufactured body 6 to be modeled. The binder solution 4 is a liquid containing a binder and a solvent or a dispersant. In the formation area 60 to which the binder solution 4 is supplied, the binding layer 41 shown in FIG. 6 is obtained. In the binding layer 41, particles of the additive manufacturing powder 1 are bound to each other by the binder, and the binding layer 41 has shape retention performance to an extent that the binding layer 41 is not broken by own weight.

The binding layer 41 may be heated simultaneously with or after the supply of the binder solution 4. Accordingly, volatilization of the solvent or the dispersant contained in the binder solution 4 is promoted, and solidification or curing of the binder promotes binding of the particles. When the binder contains a photocurable resin or a UV-curable resin, light irradiation or UV irradiation may be performed instead of heating or together with heating.

A heating temperature in the heating is not particularly limited, and is preferably 50° C. or higher and 250° C. or lower, and more preferably 70° C. or higher and 200° C. or lower. Accordingly, a sufficient amount of heat can be applied to the binding layer 41, and the volatilization of the solvent or the dispersant can be sufficiently promoted.

The binder solution 4 is not particularly limited as long as the binder solution 4 is a liquid containing a component that can bind the particles of the additive manufacturing powder 1. Examples of the solvent or the dispersant contained in the binder solution 4 include water, alcohols, ketones, carboxylic acid esters, and a mixture containing at least one of these substances. Examples of the binder contained in the binder solution 4 include fatty acids, paraffin waxes, microcrystalline waxes, polyethylene, polypropylene, polystyrene, acrylic resins, polyamide resins, polyesters, stearic acid, polyvinylpyrrolidone (PVP), polyvinyl alcohol (PVA), polyethylene glycol (PEG), urethane resins, epoxy resins, vinyl resins, unsaturated polyester resins, and phenolic resins.

### 1.4. Repetition Step

In the repetition step S106, the powder layer formation step S102 and the binder solution supply step S104 are repeated once or more until a stacked body formed by stacking a plurality of the binding layers 41 has a predetermined shape. That is, these steps are performed twice or more in total. Accordingly, the three-dimensional additively manufactured body 6 shown in FIG. 10 is obtained.

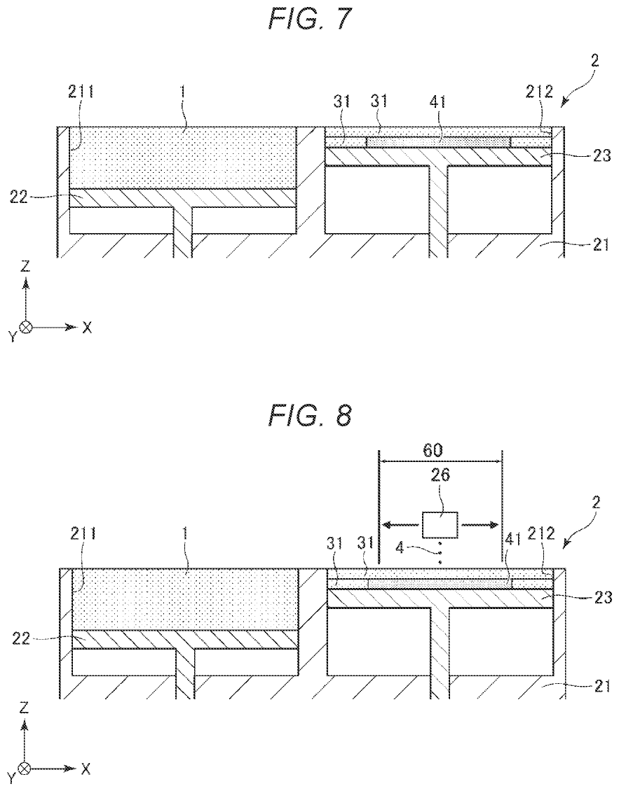

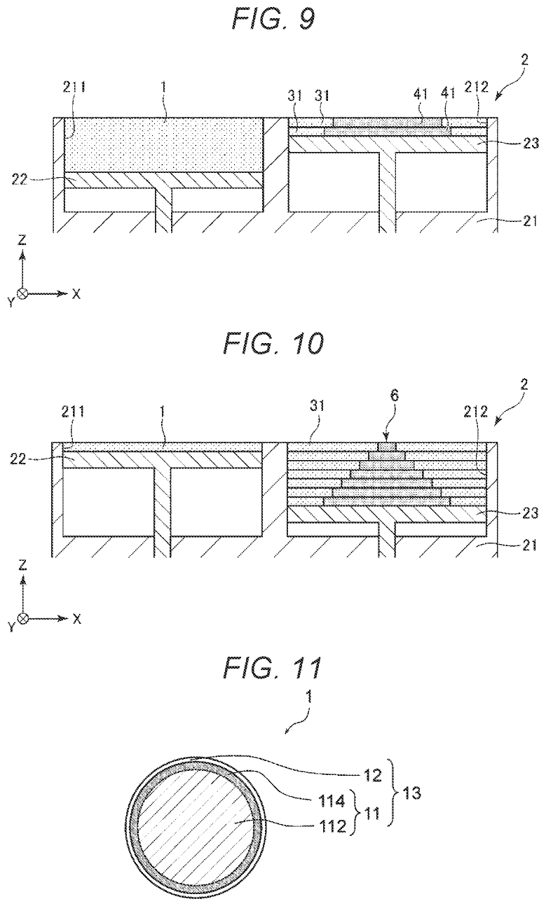

Specifically, first, as shown in FIG. 7, a new powder layer 31 is formed on the binding layer 41 shown in FIG. 6. Next, as shown in FIG. 8, the binder solution 4 is supplied to the formation area 60 of the newly formed powder layer 31. Accordingly, the binding layer 41 of a second layer shown in FIG. 9 is obtained. By repeating such operations, the additively manufactured body 6 shown in FIG. 10 is obtained.

In the powder layer 31, the additive manufacturing powder 1 that does not constitute the binding layer 41 is collected and reused as necessary, that is, used again for producing the additively manufactured body 6.

The additively manufactured body 6 obtained as described above is subjected to a sintering treatment to be described later.

### 1.5. Method for Producing Metal Sintered Body

By subjecting the additively manufactured body 6 to the sintering treatment, a metal sintered body is obtained. In the sintering treatment, the additively manufactured body 6 is heated to induce a sintering reaction.

A sintering temperature varies depending on a constituent material, a particle diameter, and the like of the additive manufacturing powder 1, and as an example, is preferably 980° C. or higher and 1330° C. or lower, and more preferably 1050° C. or higher and 1260° C. or lower. A sintering time is preferably 0.2 hours or longer and 7 hours or shorter, and more preferably 1 hour or longer and 6 hours or shorter.

An atmosphere in the sintering treatment is, for example, a reducing atmosphere such as hydrogen, an inert atmosphere such as nitrogen or argon, or a reduced-pressure atmosphere obtained by reducing a pressure of such an atmosphere. The pressure in the reduced-pressure atmosphere is not particularly limited as long as the pressure is lower than a normal pressure (100 kPa), and is preferably 10 kPa or less, and more preferably 1 kPa or less.

When the sintering treatment performed under the above-described conditions is referred to as “main sintering”, “pre-sintering” or “debindering” corresponding to a pretreatment of the main sintering may be performed on the additively manufactured body 6 as necessary. Accordingly, at least a part of the binder contained in the additively manufactured body 6 can be removed, or a sintering reaction can be induced in a portion. Accordingly, when the main sintering is performed, unintended deformation or the like can be prevented.

A temperature in the pre-sintering or the debindering is not particularly limited as long as the temperature is a temperature at which sintering of a metal powder is not completed, and is preferably 100° C. or higher and 500° C. or lower, and more preferably 150° C. or higher and 300° C. or lower. A time of the pre-sintering or the debindering in the temperature range is preferably 5 minutes or longer, more preferably 10 minutes or longer and 120 minutes or shorter, and still more preferably 20 minutes or longer and 60 minutes or shorter. An atmosphere in the pre-sintering or the debindering is, for example, an ambient atmosphere, an inert atmosphere such as nitrogen or argon, or a reduced-pressure atmosphere obtained by reducing a pressure of such an atmosphere.

The metal sintered body obtained as described above can be used as a material constituting all or a part of a component for transportation equipment such as a component for an automobile, a component for a bicycle, a component for a railway vehicle, a component for a ship, a component for an aircraft, or a component for a spacecraft, a component for an electronic device such as a component for a personal computer, a component for a mobile phone terminal, a component for a tablet terminal, or a component for a wearable terminal, a component for electrical equipment such as a refrigerator, a washing machine, or a cooling and heating machine, a component for a machine such as a machine tool or a semi-conductor manufacturing apparatus, a component for a plant such as a nuclear power plant, a thermal power plant, a hydroelectric power plant, an oil refinery, or a chemical complex, a component for a timepiece, a metal utensil, and a decorative item such as jewelry or an eyeglass frame.

### 2. Additive Manufacturing Powder

Next, the additive manufacturing powder according to the embodiment will be described.

FIG. 11 is a cross-sectional view schematically showing the additive manufacturing powder according to the embodiment.

The additive manufacturing powder 1 according to the embodiment is a powder used in various additive manufacturing methods such as the binder jet method described above.

The additive manufacturing powder 1 shown in FIG. 11 contains a plurality of surface-coated particles 13 each containing a modeling particle 11, which contains a metal material, and a coating film 12 covering a surface of the modeling particle 11. The coating film 12 contains a compound derived from a coupling agent containing a hydrophobic functional group. In the additive manufacturing powder 1 containing the surface-coated particles 13, when the surface of the modeling particle 11 is subjected to elemental analysis by X-ray photoelectron spectroscopy (XPS), a Si content is 15 atomic % or more and 40 atomic % or less. The surface-coated particles 13 in which the Si content measured by the elemental analysis by XPS is within the above-described have an excellent bonding capability with the compound derived from the coupling agent, and thus have excellent adhesion between the modeling particle 11 and the coating film 12. Therefore, the additive manufacturing powder 1 containing the surface-coated particles 13 has favorable heat resistance even after being repeatedly subjected to a heat treatment. That is, the additive manufacturing powder 1 suitable for reuse can be obtained.

The above-described Si content is preferably 17 atomic % or more and 35 atomic % or less, and more preferably 20 atomic % or more and 30 atomic % or less.

When the Si content is smaller than the lower limit value, the adhesion between the modeling particle 11 and the coating film 12 decreases. Therefore, when the additive manufacturing powder 1 is repeatedly exposed to a heat treatment, hydrophobicity imparted to the coating film 12 by the hydrophobic functional group is impaired. As a result, fluidity of the additive manufacturing powder 1 decreases, and the powder layer 31 cannot be favorably formed. On the other hand, when the Si content is larger than the upper limit value, the Si content is excessive in the vicinity of a surface of the additive manufacturing powder 1. As a result, when the produced additively manufactured body 6 is subjected to the sintering treatment, excessive Si inhibits the sintering, and mechanical properties, density, and the like of the metal sintered body decrease.

The elemental analysis by XPS can be performed under the following conditions.
X-ray photoelectron spectrometer: ESCLAB 250 manufactured by Thermo Fisher Scientific Inc.
X-ray source: AlKα ray
X-ray incident angle to sample: 45°

In the elemental analysis by XPS, photoelectrons are emitted from the vicinity of the surface of the modeling particle 11 due to the X-ray emitted toward the surface-coated particle 13. By the X-ray photoelectron spectrometer, kinetic energy of the photoelectrons is measured and elemental analysis on the vicinity of the surface is performed. Since the coating film 12 is fairly thin, a result of the elemental analysis by XPS is hardly influenced. Therefore, an analysis result of the surface-coated particle 13 can be regarded as an analysis result of the surface of the modeling particle 11. In order to more reliably eliminate an influence of the coating film 12 and other adherent substances, a sputtering treatment may be performed on the surface-coated particle 13 prior to the elemental analysis by XPS. Argon ions are preferably used in the sputtering treatment, and a treatment time is 30 seconds.

### 2.1. Modeling Particle

The metal material contained in the modeling particle 11 is not particularly limited, and may be any material as long as the material has sinterability. Examples thereof include simple substances of Fe, Ni, Co, and Ti, alloys containing such simple substances as a main component, and intermetallic compounds.

As the metal material contained in the modeling particle 11, an Fe-based metal material is preferably used. The Fe-based metal material refers to a metal material having an Fe content of more than 50% in terms of an atomic ratio. The Fe-based metal material is easily available and can be used to produce a metal sintered body having excellent mechanical properties.

The Fe-based metal material preferably contains Si. When the Fe-based metal material contains Si, Si tends to be precipitated at the surface to form an oxide. Therefore, when the Fe-based metal material contains Si, the modeling particle 11 on which Si is segregated on the surface can be easily obtained without intentionally adding Si to the surface of the modeling particle 11.

As an example, the modeling particle 11 shown in FIG. 11 has a core portion 112 and a coating portion 114 that coats a surface of the core portion 112 and contains Si. The core portion 112 is, for example, an Fe-based metal material containing Si, that is, an Fe-based alloy containing Si as a component. Meanwhile, the coating portion 114 is a Si segregation portion formed by segregation of Si in the Fe-based metal material at the surface.

Due to presence of such the coating portion 114, the modeling particle 11 that satisfies the above-described Si content over the entire particle surface can be obtained. As a result, the surface-coated particle 13 having particularly favorable adhesion between the modeling particle 11 and the coating film 12 is obtained.

The coating portion 114 may be formed by segregation of Si as described above, or may be formed by supply from the outside. The supply from the outside is, for example, film formation by a vapor-phase deposition method or a liquid-phase deposition method. Accordingly, the coating portion 114 satisfying the above-described Si content can be easily formed. In this case, the coating portion 114 preferably contains, for example, silicon, silicon oxide, silicon nitride, or silicon carbide, and more preferably contains silicon oxide. Such the coating portion 114 can prevent an unintended change in composition of the metal material due to segregation of Si. Since silicon oxide is chemically stable, modification of the metal material due to a heat treatment, moisture absorption, or the like can be prevented.

Examples of the Fe-based metal material include stainless steel such as ferritic stainless steel, austenitic stainless steel, martensitic stainless steel, precipitation-hardening stainless steel, and austenitic-ferritic (duplex) stainless steel, low-carbon steel, carbon steel, heat-resistant steel, die steel, high-speed tool steel, an Fe—Ni alloy, and an Fe—Ni—Co alloy.

Among these, stainless steel is preferably used as the Fe-based metal material. Stainless steel is a type of steel excellent in mechanical strength and corrosion resistance. Therefore, by using the additive manufacturing powder 1 made of stainless steel, a metal sintered body having excellent mechanical strength and corrosion resistance and having high shape accuracy can be efficiently produced.

Examples of the austenitic stainless steel include SUS301, SUS301L, SUS301J1, SUS302B, SUS303, SUS304, SUS304Cu, SUS304L, SUS304N1, SUS304N2, SUS304LN, SUS304J1, SUS304J2, SUS305, SUS309S, SUS310S, SUS312L, SUS315J1, SUS315J2, SUS316, SUS316L, SUS316N, SUS316LN, SUS316Ti, SUS316J1, SUS316J1L, SUS317, SUS317L, SUS317LN, SUS317J1, SUS317J2, SUS836L, SUS890L, SUS321, SUS347, SUSXM7, and SUSXM15J1.

Examples of the ferritic stainless steel include SUS405, SUS410L, SUS429, SUS430, SUS430LX, SUS430J1L, SUS434, SUS436L, SUS436J1L, SUS445J1, SUS445J2, SUS444, SUS447J1, and SUSXM27.

Examples of the martensitic stainless steel include SUS403, SUS410, SUS410S, SUS420J1, SUS420J2, and SUS440A.

Examples of precipitation-hardening the stainless steel include SUS630 and SUS631.

Examples of the austenitic-ferritic (duplex) stainless steel include SUS329J1, SUS329J3L, and SUS329J4L.

The above-described symbols are material symbols based on the JIS standards. The types of stainless steel in the specification are distinguished by the above-described material symbols.

The additively manufactured body 6 may be produced using the additive manufacturing powder 1 containing different types of stainless steel. The additively manufactured body 6 may be divided into two portions, one portion may be produced using the additive manufacturing powder 1 containing first stainless steel, and the other portion may be produced using the additive manufacturing powder 1 containing second stainless steel.

### 2.2. Coating Film

The coating film 12 is formed by reacting the coupling agent containing the hydrophobic functional group with the surface of the modeling particle 11. Therefore, the coating film 12 contains a compound derived from the coupling agent containing the hydrophobic functional group, and exhibits properties derived from the hydrophobic functional group. The coating film 12 preferably covers the entire surface of the modeling particle 11, or there may be a portion that is not covered.

Examples of the hydrophobic functional group include a cyclic structure-containing group, a fluoroalkyl group, a fluoroaryl group, a nitro group, an acyl group, or a cyano group. Among these, the hydrophobic functional group is preferably a cyclic structure-containing group, a fluoroalkyl group, or a fluoroaryl group. Such a hydrophobic functional group imparts particularly high heat resistance to the coating film 12. Accordingly, since the hydrophobicity can be maintained and moisture absorption can be inhibited even after repeated exposure to a heat treatment, the additive manufacturing powder 1 that can maintain favorable fluidity can be obtained.

The cyclic structure-containing group is a functional group containing a cyclic structure. Examples of the cyclic structure-containing group include an aromatic hydrocarbon group, an alicyclic hydrocarbon group, and a cyclic ether group.

The aromatic hydrocarbon group is a residue obtained by removing hydrogen from an aromatic hydrocarbon, and preferably has 6 or more and 20 or less carbon atoms. Examples of the aromatic hydrocarbon group include an aryl group, an alkylaryl group, an aminoaryl group, and a halogenated aryl group. Examples of the aryl group include a phenyl group, a tolyl group, a xylyl group, a naphthyl group, and an indenyl group. Examples of the alkylaryl group include a benzyl group, a methylbenzyl group, a phenethyl group, a methylphenethyl group, and a phenylbenzyl group.

The alicyclic hydrocarbon group is a residue obtained by removing hydrogen from an alicyclic hydrocarbon, and preferably has 3 or more and 20 or less carbon atoms. Examples of the alicyclic hydrocarbon group include a cycloalkyl group and a cycloalkylalkyl group. Examples of the cycloalkyl group include a cyclopropyl group, a cyclobutyl group, a cyclopentyl group, and a cyclohexyl group. Examples of the cycloalkylalkyl group include a cyclopentylmethyl group and a cyclohexylmethyl group.

Examples of the cyclic ether group include an epoxy group, a 3,4-epoxycyclohexyl group, and an oxetanyl group.

The fluoroalkyl group is an alkyl group having 1 or more and 16 or less carbon atoms or a cycloalkyl group having 3 or more and 16 or less carbon atoms, which is substituted with one or more fluorine atoms. In particular, the fluoroalkyl group is preferably a perfluoroalkyl group.

The fluoroaryl group is an aryl group having 6 or more and 20 or less carbon atoms substituted with one or more fluorine atoms. In particular, the fluoroaryl group is preferably a perfluoroaryl group.

Such hydrophobic functional groups have relatively favorable heat resistance. Therefore, the coating film 12 containing the compound derived from the coupling agent containing such hydrophobic functional groups is hardly modified even in a high-temperature environment. Therefore, the surface-coated particle 13 maintains the hydrophobicity and is less likely to absorb moisture even in a high-temperature environment, and thus the fluidity is less likely to decrease. As a result, the additive manufacturing powder 1 is obtained, which can be favorably stacked even when reused and can be used to produce the additively manufactured body 6 that is dense and that has high mechanical strength and dimensional accuracy.

Such hydrophobic functional groups have favorable hydrophobicity. Therefore, the coating film 12 containing the compound derived from the coupling agent containing such hydrophobic functional groups provides excellent fluidity for the additive manufacturing powder 1 even in a high-humidity environment.

An average thickness of the coating film 12 is not particularly limited, and is preferably 100 nm or less, more preferably 0.5 nm or more and 50 nm or less, and still more preferably 1 nm or more and 10 nm or less. Accordingly, a film thickness necessary for maintaining the coating film 12 is ensured. The average thickness of the coating film 12 is, for example, a value obtained by averaging the film thickness of the coating film 12 acquired from an observation image at five or more points when a particle cross-section of the additive manufacturing powder 1 is observed with a transmission electron microscope.

The coating film 12 may be a multilayer film in which molecules of the above-described compound are stacked in a plurality of layers, for example, two or more layers and ten or less layers, and is preferably a monomolecular film formed of the above-described compound. The thickness of the coating film 12, which is a monomolecular film, can be minimized. As a result, it is possible to obtain the additively manufactured body 6 in which an occupancy rate of the coating film 12 is low whereas an occupancy rate of the modeling particle 11 is high. Such the additively manufactured body 6 is useful in obtaining a metal sintered body with high dimensional accuracy since a shrinkage rate during the sintering treatment is reduced.

The monomolecular film is a film formed by self-assembly of the coupling agent. That is, according to the coupling agent, molecules having an affinity with the surface of the modeling particle 11 are densely arranged on the surface, and thus a film having a thickness corresponding to one molecule can be efficiently formed.

Whether the coating film 12 is a monomolecular film can be specified by, for example, qualitative and quantitative analysis in a depth direction using X-ray photoelectron spectroscopy and ion sputtering in combination. Specifically, a concentration of a component derived from the coupling agent is examined along the depth direction. When an area where the concentration of the component derived from the coupling agent is high is equal to or smaller than a molecular size of the coupling agent, the coating film 12 can be evaluated as a monomolecular film.

The coating film 12 may contain any component other than the above-described compound. In this case, from the viewpoint of reliably obtaining the above-described effects, a mass ratio of the above-described compound is preferably more than 50%, more preferably 70% or more, and still more preferably 90% or more.

### 2.2. Various Characteristics of Additive Manufacturing Powder

Next, various characteristics of the additive manufacturing powder 1 will be described.

### 2.2.1. Particle Size Distribution

For the additive manufacturing powder 1 according to the embodiment, when a volume-based particle size distribution is obtained by a laser diffraction type particle size distribution measuring apparatus, a particle diameter when a cumulative frequency is 10% from a small diameter side is defined as D10. Similarly, particle diameters when the cumulative frequency is 50% and 90% from the small diameter side are defined as D50 and D90. An example of the apparatus for measuring the particle size distribution is Microtrac HRA 9320-X100 manufactured by Nikkiso Co., Ltd.

The particle diameter D50 of the additive manufacturing powder 1 is preferably 1.0 μm or more and 15.0 μm or less, more preferably 3.0 μm or more and 12.0 μm or less, and still more preferably 4.0 μm or more and 10.0 μm or less. Accordingly, it is possible to obtain both sinterability and fluidity of the additive manufacturing powder 1. As a result, it is possible to obtain the additively manufactured body 6 that is dense and that has high mechanical strength and modeling accuracy, and it is possible to finally produce a metal sintered body having high density and surface accuracy using the additively manufactured body 6.

When the particle diameter D50 is smaller than the lower limit value, the particles of the additive manufacturing powder 1 may easily aggregate. When the aggregation occurs, the fluidity of the additive manufacturing powder 1 may decrease, and the density of the metal sintered body may decrease. On the other hand, when the particle diameter D50 is larger than the upper limit value, the sinterability of the additive manufacturing powder 1 may decrease, and the density of the metal sintered body may decrease.

A ratio (D90−D10)/D50 of a difference between the particle diameters D90 and D10 to the particle diameter D50 is preferably 0.8 or more and 2.7 or less, more preferably 1.0 or more and 2.4 or less, and still more preferably 1.2 or more and 2.2 or less. Accordingly, the particle diameter of the additive manufacturing powder 1 is relatively uniform, the fluidity can be easily increased, and the sinterability can be ensured. When the ratio (D90−D10)/D50 is smaller than the lower limit value, the particle size distribution is broad, and the fluidity may decrease. On the other hand, when the ratio (D90−D10)/D50 is larger than the upper limit value, the particle size distribution is, conversely, excessively narrow, it is difficult to increase the filling rate, and the sinterability may decrease.

### 2.2.2. Water Contact Angle

The additive manufacturing powder 1 according to the embodiment has a water contact angle of preferably 80° or more and 150° or less, more preferably 90° or more and 140° or less, and still more preferably 100° or more and 130° or less as measured in a state of being spread in a layered shape after being subjected to a heat treatment of heating at 200° C. for 72 hours in an ambient atmosphere.

The additive manufacturing powder 1 having such a water contact angle is a powder that is less likely to aggregate and that has high fluidity even when repeatedly subjected to a heat treatment. Therefore, the additive manufacturing powder 1 has excellent filling properties even when reused a plurality of times. Accordingly, even when the additive manufacturing powder 1 reused a plurality of times is used, the additively manufactured body 6 that is dense and that has high mechanical strength and dimensional accuracy is obtained. Then, the additively manufactured body 6, which can be used to produce a metal sintered body excellent in relative density, mechanical strength, and dimensional accuracy by performing the sintering treatment on the additively manufactured body 6, is obtained.

The additive manufacturing powder 1 having a water contact angle within the above-described range has an excellent affinity with the binder solution 4. Therefore, when the binder solution 4 is supplied after the additive manufacturing powder 1 is spread to form the powder layer 31, the binder solution 4 easily permeates the formation area 60 of the powder layer 31. Accordingly, the binder solution 4 can uniformly permeate the formation area 60, and thus the additively manufactured body 6 having high dimensional accuracy can be produced.

When the water contact angle is smaller than the lower limit value, the additive manufacturing powder 1 is likely to absorb moisture and aggregate, and the fluidity may decrease. On the other hand, although the water contact angle may be larger than the upper limit value, in this case, since the hydrophobicity is excessively large, permeability of the binder solution 4 may decrease depending on a composition of the binder solution 4. Accordingly, homogeneity of the additively manufactured body 6 may decrease.

The water contact angle in the additive manufacturing powder 1 can be measured by the following procedure. First, the additive manufacturing powder 1 is subjected to a heat treatment of heating at 200° C. for 72 hours in an ambient atmosphere. Next, a double-sided tape is attached to a flat surface. Next, the additive manufacturing powder 1 subjected to the heat treatment is spread on the double-sided tape. As the double-sided tape, for example, a polyester adhesive tape No. 31B, manufactured by Nitto Denko Corporation, of a type having a total thickness of 0.080 mm is used. Then, the spread additive manufacturing powder 1 is lightly pressed by a plate-like member. Next, the excessive additive manufacturing powder 1 is blown off by an air blower. Accordingly, a test specimen for contact angle measurement is obtained. An example of the air blower is a manual air blower used for cleaning a camera. Then, a tip of the air blower is fixed at a position 3 cm away from the test specimen and blowing is performed three times.

Next, a water contact angle of the test specimen is measured by a θ/2 method using a contact angle measuring apparatus Drop Master 500 manufactured by Kyowa Interface Science Co., Ltd. Measurement conditions are an air temperature of 25° C. and a relative humidity of 50%±5%. An amount of water dropped is 3 μL, and the measurement is performed 5 seconds after landing.

### 3. Method for Producing Additive Manufacturing Powder

Next, a method for producing an additive manufacturing powder according to the embodiment will be described.

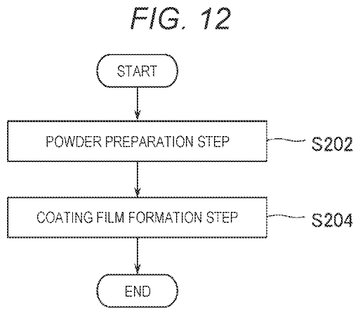

FIG. 12 is a process diagram showing a configuration of the method for producing an additive manufacturing powder according to the embodiment. In the following description, a method for producing the additive manufacturing powder 1 will be described as an example.

The method for producing an additive manufacturing powder shown in FIG. 12 includes a powder preparation step S202 of preparing the modeling particle 11, and a coating film formation step S204 of forming the coating film 12.

### 3.1. Powder Preparation Step

In the powder preparation step S202, a metal powder to be used as the modeling particle 11 is prepared.

The metal powder may be produced by any production method, and is produced by, for example, an atomization method. In the atomization method, a molten metal is caused to flow down from a crucible and collide with a fluid such as a liquid or a gas ejected at a high speed. The molten metal colliding with the fluid falls inertially, and therefore, at this time, becomes a spherical liquid droplet. As a result, it is possible to produce a metal powder having high circularity and a relatively small specific surface area despite a relatively small diameter.

Examples of the atomization method include a water atomization method, a gas atomization method, and a rotating water jet atomization method, depending on difference in a type of a cooling medium and an apparatus configuration.

A flow rate of the molten metal varies depending on an apparatus size and the like, and is preferably more than 1.0 [kg/min] and 20.0 [kg/min] or less, and more preferably 2.0 [kg/min] or more and 10.0 [kg/min] or less. Accordingly, it is possible to optimize an amount of the molten metal flowing down during a certain time, and thus a metal powder having a narrow particle size distribution and being sufficiently spherical can be efficiently produced. As a result, it is possible to produce a metal powder having high circularity and a relatively small specific surface area despite a relatively small diameter.

A temperature (casting temperature) of the molten metal in the crucible is preferably set, with respect to a melting point Tm [° C.] of a constituent material of the additive manufacturing powder, to Tm+100° C. or more and Tm+350° C. or less, more preferably Tm+180° C. or more and Tm+320° C. or less, and still more preferably Tm+250° C. or more and Tm+300° C. or less. Accordingly, it is possible to ensure a time during which the molten metal is present longer than that in the related art when the molten metal is refined and solidified by various atomization methods. As a result, it is possible to produce a metal powder having a small diameter, high circularity and a relatively small specific surface area.

In various atomization methods, an outer diameter of a fine stream when the molten metal flows down is not particularly limited, and is preferably 3.0 mm or less, more preferably 0.3 mm or more and 2.0 mm or less, and still more preferably 0.5 mm or more and 1.5 mm or less. Accordingly, the fluid can be easily and uniformly applied to the molten metal, and thus liquid droplets having an appropriate size can be easily and uniformly scattered. As a result, it is possible to produce the metal powder having the average particle diameter as described above with a narrow particle size distribution.

The produced metal powder may be classified as necessary. Examples of classification methods include dry classification such as sieving classification, inertial classification, and centrifugal classification, and wet classification such as sedimentation classification.

Thereafter, the produced metal powder may be subjected to an annealing treatment (heat treatment). Accordingly, it is possible to efficiently produce the modeling particle 11 having the core portion 112 and the coating portion 114 shown in FIG. 11.

In the annealing treatment, as described above, Si contained in the metal material is segregated at the surface. Therefore, in the powder preparation step S202, a metal particle is made of a metal material containing Si, and the annealing treatment is performed on the metal particle to precipitate Si at a surface. Accordingly, the modeling particle 11 is obtained.

Conditions of the annealing treatment are not particularly limited, and preferably a heating temperature is 600° C. or higher and 1000° C. or lower and a heating time is 10 minutes or longer and 3 hours or shorter, and more preferably the heating temperature is 700° C. or higher and 900° C. or lower and the heating time is 30 minutes or longer and 2 hours or shorter. Accordingly, the coating portion 114 satisfying the above-described Si content can be formed with a higher probability. A heating atmosphere is, for example, an inert atmosphere such as nitrogen or an ambient atmosphere.

Meanwhile, when the coating portion 114 is formed by various film formation methods, as the film formation method, a vapor phase deposition method is preferably used, and an atomic layer deposition (ALD) method is more preferably used. In the ALD method, since a raw material can be deposited at an atomic layer level, the dense and thin coating portion 114 can be formed. In the ALD method, the raw material, an oxidizing agent, or the like favorably flows into a recess or a shaded portion. Therefore, the coating portion 114 having a high coverage ratio can be formed by using the ALD method. As a result, in the coating film formation step S204 to be described later, the coverage ratio of the coating film 12 can also be increased.

The powder preparation step S202 may not be performed to produce the modeling particle 11 as described above as long as the modeling particle 11 can be obtained.

### 3.2. Coating Film Formation Step

In the coating film formation step S204, the coating film 12 is formed at the surface of the modeling particle 11. In this step, the coupling agent containing the hydrophobic functional group is reacted with the modeling particle 11. Accordingly, the coupling agent adheres to the surface of the modeling particle 11.

Examples of such an operation include the following three operations.

A first operation is, for example, an operation of heating the inside of a chamber after charging both the modeling particles 11 and the coupling agent into the chamber.

A second operation is, for example, an operation of spraying the coupling agent into the chamber while stirring the modeling particles 11 after the modeling particles 11 are charged into the chamber.

A third operation is, for example, an operation of adding water, the coupling agent, an alkaline solution such as ammonia or sodium hydroxide, and the modeling particles 11 to a primary alcohol such as methanol, ethanol, or isopropyl alcohol, followed by stirring, filtering, and drying.

Examples of the coupling agent include a silane coupling agent, a titanium coupling agent, and a zirconium coupling agent.

The following chemical formula is an example of a molecular structure of the silane coupling agent.

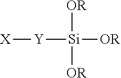

In the formula, X is a functional group, Y is a spacer, and OR is a hydrolyzable group. R is, for example, a methyl group or an ethyl group.

Examples of the spacer include an alkylene group, an arylene group, an aralkylene group, and an alkylene ether group.

Examples of the hydrolyzable group include an alkoxy group, a halogen atom, a cyano group, an acetoxy group, and an isocyanate group, and among these, in the case of an alkoxy group, silanol is produced by hydrolysis. The silanol reacts with a hydroxy group generated at the surface of the modeling particle 11, and the coupling agent adheres to the surface of the modeling particle 11. When the above-described Si content is within the above-described range, the coupling agent is likely to adhere uniformly without unevenness. As a result, the coating film 12 having a high coverage ratio and being close to a monomolecular layer is obtained.

The coupling agent may contain at least one of such hydrolyzable groups, and preferably contains two or more, and more preferably contains three hydrolyzable groups as in the formula. For example, a coupling agent whose hydrolyzable group is an alkoxy group preferably contains a dialkoxy group, and more preferably contains a trialkoxy group. The coupling agent containing a trialkoxy group reacts with three hydroxy groups generated at the surface of the modeling particle 11. Therefore, favorable adhesion to the modeling particle 11 is obtained. Since the coupling agent containing a trialkoxy group also has excellent film-forming properties, it is possible to obtain the coating film 12 having excellent continuity. Such the coating film 12 contributes to further improve the heat resistance and the fluidity of the additive manufacturing powder 1.

In a coupling agent containing a trialkoxy group, even when the hydrophobic functional group is thermally decomposed after the formation of the coating film 12, the surface of the modeling particle 11 can be continuously covered by a remainder. Therefore, a decrease in hydrophobicity can be prevented.

Here, examples of the coupling agent containing the hydrophobic functional group are described. Examples of the coupling agent containing an aromatic hydrocarbon group include:
phenyltrimethoxysilane represented by the following formula (A-1);

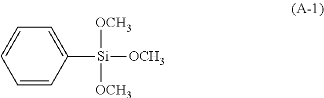 [SMILES: CO[Si](OC)(OC)c1ccccc1]

phenyltriethoxysilane represented by the following formula (A-2);

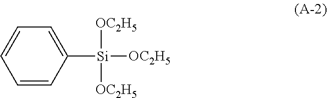 [SMILES: CCO[Si](OCC)(OCC)c1ccccc1]

dimethoxydiphenylsilane represented by the following formula (A-3);

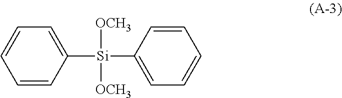 [SMILES: CO[Si](OC)(c1ccccc1)c1ccccc1]

2,2-dimethoxy-1-phenyl-1-aza-2-silacyclopentane represented by the following formula (A-4);

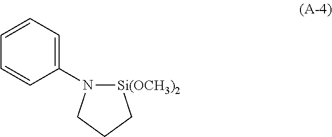

3-phenoxypropyltrichlorosilane represented by the following formula (A-11);

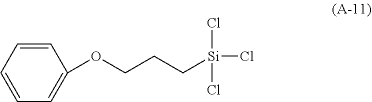 [SMILES: Cl[Si](Cl)(Cl)CCCOc1ccccc1]

phenyltriacetoxysilane represented by the following formula (A-12);

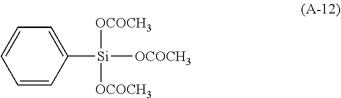

triethoxy (p-tolyl) silane represented by the following formula (A-13);

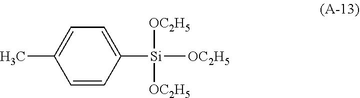 [SMILES: CCO[Si](OCC)(OCC)c1ccc(C)cc1]

p-aminophenyltrimethoxysilane represented by the following formula (A-14);

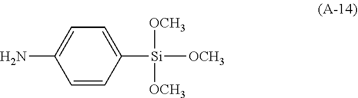 [SMILES: CO[Si](OC)(OC)c1ccc(N)cc1]

m-aminophenyltrimethoxysilane represented by the following formula (A-15); and

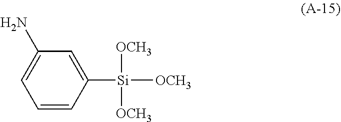 [SMILES: CO[Si](OC)(OC)c1cccc(N)c1]

((chloromethyl) phenylethyl) trimethoxysilane represented by the following formula (A-16).

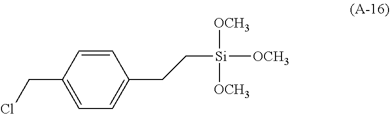 [SMILES: CO[Si](CCc1ccc(CCl)cc1)(OC)OC]

Examples of the coupling agent containing a cyclic ether group include:
3-glycidoxypropylmethyldimethoxysilane represented by the following formula (A-5);

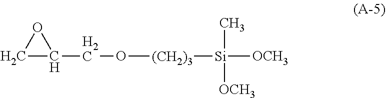

3-glycidoxypropyltrimethoxysilane represented by the following formula (A-6);

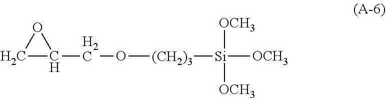

3-glycidoxypropylmethyldiethoxysilane represented by the following formula (A-7); and

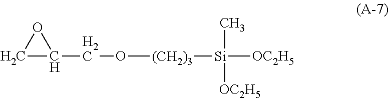

3-glycidoxypropyltriethoxysilane represented by the following formula (A-8).

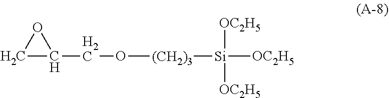

Examples of the coupling agent containing a fluoroalkyl group include:
trimethoxy (3, 3,3-trifluoropropyl) silane represented by the following formula (B-1);

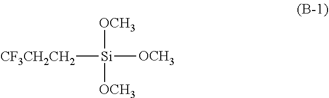

trimethoxy (1H, 1H, 2H, 2H-tridecafluoro-n-octyl) silane represented by the following formula (B-2); and

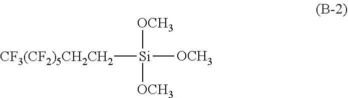

trimethoxy (1H, 1H, 2H, 2H-nonafluorohexyl) silane represented by the following formula (B-3).

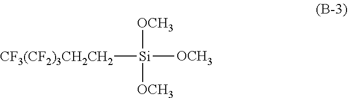

Examples of the coupling agent containing a fluoroaryl group include:
trimethoxy (11-pentafluorophenoxyundecyl) silane represented by the following formula (C-1); and

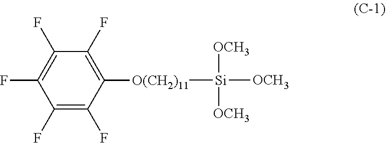

pentafluorophenyldimethylchlorosilane represented by the following formula (C-2).

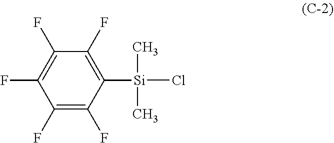

An amount of the coupling agent charged is not particularly limited, and is preferably 0.01 mass % or more and 1.00 mass % or less, and more preferably 0.05 mass % or more and 0.50 mass % or less, with respect to the modeling particle 11.

The coupling agent is supplied by a method of static placement in the chamber or spraying into the chamber.

Thereafter, the modeling particle 11 to which the coupling agent adheres is heated. Accordingly, the coating film 12 is formed at the surface of the modeling particle 11, and the additive manufacturing powder 1 is obtained. The unreacted coupling agent can be removed by heating.

A heating temperature for the modeling particle 11 to which the coupling agent adheres is not particularly limited, and is preferably 50° C. or higher and 300° C. or lower, and more preferably 100° C. or higher and 250° C. or lower. A heating time is preferably 10 minutes or longer and 24 hours or shorter, and more preferably 30 minutes or longer and 10 hours or shorter. An atmosphere in the heat treatment is, for example, ambient atmosphere or an inert gas atmosphere.

### 4. Effects of Embodiment

As described above, the additive manufacturing powder 1 according to the embodiment is an additive manufacturing powder used for producing the additively manufactured body 6 to be formed into a metal sintered body by sintering, and includes the modeling particle 11 containing a metal material and the coating film 12 provided at the surface of the modeling particle 11. The coating film 12 contains a compound derived from a coupling agent containing a hydrophobic functional group. In the additive manufacturing powder 1, when the surface of the modeling particle 11 is subjected to elemental analysis by X-ray photoelectron spectroscopy (XPS), a Si content is 15 atomic % or more and 40 atomic % or less.

According to such a configuration, in the additive manufacturing powder 1, a bonding capability between the modeling particle 11 and the compound derived from the coupling agent is favorable. Therefore, the additive manufacturing powder 1 having favorable heat resistance can be obtained even after being repeatedly subjected to a heat treatment. That is, the additive manufacturing powder 1 suitable for reuse can be obtained.

The metal material contained in the modeling particle 11 is preferably an Fe-based metal material containing Si.

According to such a configuration, Si contained in the modeling particle 11 is precipitated at the surface to form an oxide. Accordingly, the modeling particle 11 at which Si is segregated at the surface can be easily obtained without intentionally adding Si to the surface of the modeling particle 11.

The modeling particle 11 includes the core portion 112 and the coating portion 114. The core portion 112 is made of a metal material. The coating portion 114 coats the surface of the core portion 112 and contains Si.

According to such a configuration, the modeling particle 11 that satisfies the above-described Si content over the entire particle surface can be obtained. As a result, the additive manufacturing powder 1 having particularly favorable adhesion between the modeling particle 11 and the coating film 12 is obtained.

The coating portion 114 preferably contains silicon oxide.

According to such a configuration, it is possible to prevent an unintended change in composition of the metal material due to segregation of Si. Since silicon oxide is chemically stable, modification of the metal material due to a heat treatment, moisture absorption, or the like can be prevented.

The hydrophobic functional group is preferably a cyclic structure-containing group, a fluoroalkyl group, or a fluoroaryl group.

Accordingly, particularly high heat resistance can be imparted to the coating film 12. Accordingly, since the hydrophobicity can be maintained and moisture absorption can be inhibited even after repeated exposure to a heat treatment, the additive manufacturing powder 1 that can maintain favorable fluidity can be obtained.

The additive manufacturing powder 1 has a water contact angle of preferably 80° or more and 150° or less as measured at 25° C. by a θ/2 method in a state of being spread in a layered shape after being subjected to a heat treatment of heating at 200° C. for 72 hours in an ambient atmosphere.

According to such a configuration, it is possible to obtain the additive manufacturing powder 1 that is less likely to aggregate and that has high fluidity even when repeatedly subjected to a heat treatment. The additive manufacturing powder 1 has excellent filling properties even when reused a plurality of times. Accordingly, even when the additive manufacturing powder 1 reused a plurality of times is used, the additively manufactured body 6 that is dense and that has high mechanical strength and dimensional accuracy is obtained.

When a volume-based particle size distribution is obtained by a laser diffraction type particle size distribution measuring apparatus, the particle diameter D50 is preferably 1.0 μm or more and 15.0 μm or less, and the ratio (D90−D10)/D50 is preferably 0.8 or more and 2.7 or less, in which D10 is a particle diameter when a cumulative frequency is 10% from a small diameter side, D50 is a particle diameter when the cumulative frequency is 50% from the small diameter side, and D90 is a particle diameter when the cumulative frequency is 90% from the small diameter side.

According to such a configuration, it is possible to obtain both sinterability and fluidity of the additive manufacturing powder 1. As a result, the additively manufactured body 6 that is dense and that has high mechanical strength and modeling accuracy can be obtained.

The method for producing an additive manufacturing powder according to the embodiment is a method for producing an additive manufacturing powder used for producing the additively manufactured body 6 to be formed into a metal sintered body by sintering, and includes the coating film formation step S204. In the coating film formation step S204, a coupling agent containing a hydrophobic functional group is reacted with the surface of the modeling particle 11 containing the metal material to form the coating film 12 containing a compound derived from the coupling agent. When the surface of the modeling particle 11 is subjected to elemental analysis by X-ray photoelectron spectroscopy (XPS), the Si content is 15 atomic % or more and 40 atomic % or less.

According to such a configuration, the additive manufacturing powder 1, in which a bonding capability between the modeling particle 11 and the compound derived from the coupling agent is favorable, is obtained. The additive manufacturing powder 1 has favorable heat resistance even after being repeatedly subjected to a heat treatment. Therefore, the additive manufacturing powder 1 is suitable for reuse in an additive manufacturing method.

The method for producing an additive manufacturing powder according to the embodiment may include the powder preparation step S202. In the powder preparation step S202, an annealing treatment (heat treatment) is performed on a metal particle made of a metal material containing Si, Si is precipitated at a surface of the metal particle, and the modeling particle 11 is obtained.

According to such a configuration, it is possible to efficiently produce the modeling particle 11 whose Si content at the surface is within the above-described range.

In the method for producing an additive manufacturing powder according to the embodiment, the modeling particle 11 may have the core portion 112 made of the metal material and the coating portion 114 that coats the surface of the core portion 112 and contains Si. In this case, the powder preparation step S202 (the step of obtaining the modeling particle) may include an operation of forming the coating portion 114 using an ALD method.

In the ALD method, since a raw material can be deposited at an atomic layer level, the dense and thin coating portion 114 can be formed. In the ALD method, the raw material, an oxidizing agent, or the like favorably flows into a recess or a shaded portion. Therefore, the coating portion 114 having a high coverage ratio can be formed by using the ALD method. As a result, the coverage ratio of the coating film 12 can also be increased.

The additively manufactured body 6 according to the embodiment contains the additive manufacturing powder 1 and a binder particles of the additive manufacturing powder 1.

Even when the additively manufactured body 6 is produced using the additive manufacturing powder 1 repeatedly subjected to a heat treatment, the additively manufactured body 6 is dense and has high mechanical strength and modeling accuracy. Therefore, a metal sintered body having high density and surface accuracy can be efficiently obtained by sintering such the additively manufactured body 6. Since it is possible to reduce a waste amount of the additive manufacturing powder 1 which is provided for additive manufacturing but is not used, it is possible to produce a high-quality metal sintered body while reducing a production cost.

Although the additive manufacturing powder, the method for producing an additive manufacturing powder, and the additively manufactured body according to the present disclosure are described above based on the shown embodiment, the present disclosure is not limited thereto. For example, the additive manufacturing powder and the additively manufactured body according to the present disclosure may be obtained by adding any component to the embodiment.

The method for producing an additive manufacturing powder according to the present disclosure may have any desired step added to the embodiment.

### EXAMPLES

Next, specific examples of the present disclosure will be described.

### 5. Production of Additive Manufacturing Powder

A metal powder used as an additive manufacturing powder in each of samples No. 1 to No. 21 was produced by a water atomization method. Next, the obtained metal powder was subjected to an annealing treatment or a film formation treatment shown in Tables 2 to 4. The annealing treatment is a treatment of heating at 800° C. for 1 hour in a nitrogen atmosphere. The film formation treatment is a treatment of forming a film of silicon oxide with a film thickness of 5 nm by an ALD method. The metal powders of a part of the samples No. were not subjected to any of these treatments. Next, a coating film was formed at each obtained metal powder using a coupling agent. Accordingly, an additive manufacturing powder was obtained. A steel type of each metal powder used in the additive manufacturing powder is shown in Tables 1 to 4.

TABLE 1

| | Steel type | Category |
|---|---|---|
| Steel type 1 | SUS630 | Precipitation-hardening |
| | (17-4PH) | stainless steel |
| Steel type 2 | SUS316L | Austenitic stainless steel |

Symbols of chemical formulae shown in Tables 2 to 4 correspond to the following compounds.
A-1: phenyltrimethoxysilane
A-6: 3-glycidoxypropyltrimethoxysilane
B-1: trimethoxy (3, 3,3-trifluoropropyl) silane
C-1: trimethoxy (11-pentafluorophenoxyundecyl) silane
D-3: decyltrimethoxysilane
D-4: octadecyltrimethoxysilane
D-5: vinyltrimethoxysilane

### 6. Acquisition of Characteristics of Additive Manufacturing Powder

For each additive manufacturing powder, a Si content, a representative particle diameter, and a water contact angle after a heat treatment were measured. The measured water contact angle was evaluated in view of the following evaluation criteria. Measurement results and evaluation results are shown in Tables 2 to 4.
A: the contact angle is 110° or more and 150° or less
B: the contact angle is 95° or more and less than 110°
C: the contact angle is 80° or more and less than 95°
D: the contact angle is less than 80° or more than 150°

In Tables 2 to 4, among the additive manufacturing powders of the respective samples No., those corresponding to the present disclosure were each denoted as “Example”, and those not corresponding to the present disclosure were each denoted as “Comparative example”.

### 7. Evaluation of Additive Manufacturing Powder

### 7.1. Dispersibility

For each additive manufacturing powder, dispersibility in water was evaluated by the following procedure.

First, each additive manufacturing powder immediately after preparation was immersed in pure water to prepare a suspension, and then the suspension was sufficiently stirred by hand shaking. Next, hydrophobicity of the powder was evaluated by visually observing the stirred suspension and evaluating dispersibility of the additive manufacturing powder in view of the following evaluation criteria. Evaluation results are shown in Tables 2 to 4. In Tables 2 to 4, the evaluation results are referred to as dispersibility before a heat treatment.
A: there is almost no dispersed powder (the powder has high hydrophobicity)
B: a slight amount of powder is dispersed (hydrophobicity of the powder is slightly high)
C: a large amount of powder is dispersed (hydrophobicity of the powder is slightly low)
D: almost all of the powder is dispersed (hydrophobicity of the powder is low)

Subsequently, the additive manufacturing powder was subjected to a heat treatment of heating at 200° C. for 72 hours in an ambient atmosphere. Thereafter, each additive manufacturing powder immediately after heating was immersed in pure water to prepare a suspension, and then the suspension was sufficiently stirred by hand shaking. Next, the hydrophobicity of the powder was evaluated by visually observing the stirred suspension and evaluating the dispersibility of the additive manufacturing powder in view of the above-described evaluation criteria. Evaluation results are shown in Tables 2 to 4. In Tables 2 to 4, the evaluation results are referred to as dispersibility after the heat treatment.

### 7.2. Mechanical Strength of Additively Manufactured Body

First, each additive manufacturing powder was subjected to a heat treatment in the same manner as in 7.1.

Next, using each additive manufacturing powder subjected to the heat treatment, an additively manufactured body having a rectangular parallelepiped shape was prepared by a binder jet method. A size of the prepared additively manufactured body was 40 mm in length, 20 mm in width, and 5 mm in thickness. A polyvinyl alcohol aqueous solution was used as a binder solution.

Next, a bending load of the prepared additively manufactured body was measured using a three-point bending test fixture. Then, a bending stress σ of the additively manufactured body was calculated according to the following equation.

$$σ = \frac{3 FL}{2 b {h}^{2}} \qquad Math . 1$$

In the above-described equation, F is the bending load, L is a distance between fulcrums of the three-point bending test fixture, b is the width of the additively manufactured body, and h is the thickness of the additively manufactured body.

In order to prepare the additively manufactured body, an amount of the binder used was 70 mass % of the additive manufacturing powder. Then, calculation results were evaluated in view of the following evaluation criteria. Evaluation results are shown in Tables 2 to 4.
A: the mechanical strength of the additively manufactured body is high (the bending stress σ is 25 N/cm² or more)
B: the mechanical strength of additively the manufactured body is slightly high (the bending stress σ is 20 N/cm² or more and less than 25 N/cm²)
C: the mechanical strength of the additively manufactured body is slightly low (the bending stress σ is 15 N/cm² or more and less than 20 N/cm²)
D: the mechanical strength of the additively manufactured body is low (the bending stress σ is less than 15 N/cm²)

TABLE 2

| | | | | | Configuration of additive manufacturing powder | | | | |
|---|---|---|---|---|---|---|---|---|---|
| | | | | | | Representative | | | |
| | | Production method | | | | particle diameter | | | |
| | | | | Film | | | | | (D90 − |
| | | Steel | Annealing | formation | Si | | | | D10)/ |
| Sample | | type | treatment | treatment | content | D10 | D50 | D90 | D50 |
| No. | Classification | — | — | — | atomic % | μm | μm | μm | — |
| 1 | Examples | 1 | Yes | No | 16 | 3.4 | 7.1 | 14.3 | 1.5 |
| 2 | Examples | 1 | Yes | No | 20 | 3.4 | 7.0 | 17.4 | 2.0 |
| 3 | Examples | 1 | Yes | No | 25 | 2.9 | 6.8 | 15.4 | 1.8 |
| 4 | Examples | 1 | Yes | No | 25 | 2.9 | 7.0 | 19.0 | 2.3 |
| 5 | Examples | 1 | Yes | No | 30 | 3.7 | 7.5 | 14.5 | 1.4 |
| 6 | Examples | 1 | Yes | No | 38 | 2.9 | 6.9 | 15.5 | 1.8 |
| 7 | Examples | 1 | No | SiO₂ | 23 | 2.9 | 6.9 | 15.5 | 1.8 |
| 8 | Examples | 1 | No | SiO₂ | 36 | 2.9 | 6.9 | 15.5 | 1.8 |
| 9 | Comparative | 1 | No | No | 13 | 2.9 | 7.0 | 16.3 | 1.9 |
| | Example | | | | | | | | |
| 10 | Comparative | 1 | Yes | No | 44 | 2.9 | 7.1 | 15.6 | 1.8 |
| | Example | | | | | | | | |

| | | | | Evaluation result | | |
|---|---|---|---|---|---|---|
| | Configuration of additive manufacturing powder | | | | | Mechanical |
| | Coupling agent | | Contact | Dispersibility | | strength of |
| | Hydrophobic | | angle after | Before | After | additively |
| | functional | Chemical | heat | heat | heat | manufactured |
| Sample | group | formula | treatment | treatment | treatment | body |
| No. | — | — | — | — | — | — |
| 1 | Phenyl group | A-1 | B | A | B | B |
| 2 | Phenyl group | A-1 | A | A | A | A |
| 3 | Phenyl group | A-1 | A | A | A | A |
| 4 | Phenyl group | A-1 | A | A | A | B |
| 5 | Phenyl group | A-1 | A | A | A | A |
| 6 | Phenyl group | A-1 | B | A | B | B |
| 7 | Phenyl group | A-1 | A | A | A | A |
| 8 | Phenyl group | A-1 | B | A | B | B |
| 9 | Phenyl group | A-1 | D | A | D | D |
| 10 | Phenyl group | A-1 | A | A | A | C |

TABLE 3

| | | | | | Configuration of additive manufacturing powder | | | | |
|---|---|---|---|---|---|---|---|---|---|
| | | | | | | Representative | | | |
| | | Production method | | | | particle diameter | | | |
| | | | | Film | | | | | (D90 − |
| | | Steel | Annealing | formation | Si | | | | D10)/ |
| Sample | | type | treatment | treatment | content | D10 | D50 | D90 | D50 |
| No. | Classification | — | — | — | atomic % | μm | μm | μm | — |
| 11 | Examples | 1 | Yes | No | 24 | 2.4 | 4.2 | 7.5 | 1.2 |
| 12 | Examples | 1 | Yes | No | 24 | 2.4 | 4.2 | 7.5 | 1.2 |
| 13 | Examples | 1 | Yes | No | 24 | 2.4 | 4.2 | 7.5 | 1.2 |
| 14 | Examples | 1 | Yes | No | 24 | 2.4 | 4.2 | 7.5 | 1.2 |
| 15 | Examples | 1 | Yes | No | 24 | 2.4 | 4.2 | 7.5 | 1.2 |
| 16 | Examples | 1 | Yes | No | 24 | 2.4 | 4.2 | 7.5 | 1.2 |

| | | | | Evaluation result | | |
|---|---|---|---|---|---|---|
| | Configuration of additive manufacturing powder | | | | | Mechanical |
| | Coupling agent | | Contact | Dispersibility | | strength of |
| | Hydrophobic | | angle after | Before | After | additively |
| | functional | Chemical | heat | heat | heat | manufactured |
| Sample | group | formula | treatment | treatment | treatment | body |
| No. | — | — | — | — | — | — |
| 11 | Epoxy group | A-6 | B | A | B | B |
| 12 | Fluoroalkyl group | B-1 | A | A | A | A |
| 13 | Fluorophenyl group | C-1 | A | A | A | A |
| 14 | Decyl group | D-3 | B | A | B | B |
| 15 | Octadecyl group | D-4 | B | A | B | B |
| 16 | Vinyl group | D-5 | B | A | B | B |

TABLE 4

| | | | | | Configuration of additive manufacturing powder | | | | |
|---|---|---|---|---|---|---|---|---|---|
| | | | | | | Representative | | | |
| | | Production method | | | | particle diameter | | | |
| | | | | Film | | | | | (D90 − |
| | | Steel | Annealing | formation | Si | | | | D10)/ |
| Sample | | type | treatment | treatment | content | D10 | D50 | 090 | D50 |
| No. | Classification | — | — | — | atomic % | μm | μm | μm | — |
| 17 | Examples | 2 | Yes | No | 18 | 4.7 | 8.3 | 16.0 | 1.4 |
| 18 | Examples | 2 | Yes | No | 23 | 5.0 | 9.1 | 17.0 | 1.3 |
| 19 | Examples | 2 | Yes | No | 37 | 4.3 | 7.2 | 14.7 | 1.4 |
| 20 | Comparative | 2 | No | No | 10 | 2.5 | 9.0 | 21.0 | 2.1 |
| | Example | | | | | | | | |
| 21 | Comparative | 2 | No | SiO₂ | 46 | 2.1 | 6.5 | 13.0 | 1.7 |
| | Example | | | | | | | | |

| | | | | Evaluation result | | |
|---|---|---|---|---|---|---|
| | Configuration of additive manufacturing powder | | | | | Mechanical |
| | Coupling agent | | Contact | Dispersibility | | strength of |
| | Hydrophobic | | angle after | Before | After | additively |
| | functional | Chemical | heat | heat | heat | manufactured |
| Sample | group | formula | treatment | treatment | treatment | body |
| No. | — | — | — | — | — | — |
| 17 | Phenyl group | A-1 | A | A | B | A |
| 18 | Phenyl group | A-1 | A | A | A | A |
| 19 | Phenyl group | A-1 | A | A | B | B |
| 20 | Phenyl group | A-1 | D | A | D | D |
| 21 | Phenyl group | A-1 | A | A | A | C |

### 7.3. Consideration on Evaluation Results

As shown in Tables 2 to 4, the additive manufacturing powder of each Example has low dispersibility in water even after the heat treatment at a high temperature of 200° C. for a long time of 72 hours. The additively manufactured body prepared using the additive manufacturing powder after the heat treatment has favorable mechanical strength. Therefore, it is confirmed that in the additive manufacturing powder in each Example, hydrophobicity of the coating film is favorably maintained even when the additive manufacturing powder is repeatedly subjected to the heat treatment, and a decrease in fluidity due to moisture absorption or the like is prevented. It is considered that such a result is caused by the fact that the Si content is optimized at the surface of the additive manufacturing powder in each Example.

From the above, it is clear that the additive manufacturing powder according to the present disclosure has favorable heat resistance even when repeatedly subjected to a heat treatment.

### 8. Comparison of Heat Resistance Time

Table 5 shows results of comparing heat resistance of coating films formed by a coupling agent at two types of substrates having different constituent materials.

Sample No. A shown in Table 5 is a specimen on which the coating film is formed by the coupling agent at a substrate made of a quartz crystal. Sample No. B shown in Table 5 is a specimen at which the coating film is formed by the coupling agent at a substrate made of stainless steel SUS630. In both cases, a silane coupling agent containing a phenyl group as a hydrophobic functional group was used as the coupling agent.

Each specimen was subjected to a heat treatment at 200° C. for 72 hours in an ambient atmosphere. Then, states of the coating films before the heat treatment (initial) and 1 hour, 24 hours, 48 hours, and 72 hours after start of the heat treatment were compared. Each state of the coating film was evaluated based on intensity of a peak derived from carbon atoms in an XPS spectrum. That is, since carbon atoms in each specimen were derived from the coupling agent, a remaining amount of the coating film was evaluated based on the intensity of the peak. In Table 5, an initial peak intensity is 1, and a relative value of the peak intensity at each time is shown.

TABLE 5

| | | Intensity of peak derived from | | | | |
|---|---|---|---|---|---|---|
| | | carbon atoms | | | | |
| | | | Time of heat treatment | | | |
| | Constituent | | 1 | 24 | 48 | 72 |
| Sample | material of | Initial | hour | hours | hours | hours |
| No. | substrate | — | — | — | — | — |
| A | Quartz crystal | 1.00 | 1.03 | 0.83 | 0.91 | 0.92 |
| B | SUS630 (17-4PH) | 1.00 | 0.26 | 0.11 | 0.07 | 0.05 |

As shown in Table 5, in sample No. A, the intensity of the peak derived from the carbon atoms is equal to that before the heat treatment even after the heat treatment for 72 hours. Therefore, it is found that in sample No. A, the coating film sufficiently remains even after the heat treatment. A Si content of a surface of sample No. A measured by elemental analysis using XPS is 33 atomic %.

In contrast, in Sample No. B, the intensity of the peak derived from the carbon atoms decreases with a lapse of time of the heat treatment. Therefore, it is considered that, in Sample No. B, the coating film disappears or is deactivated along with the heat treatment. A Si content of a surface of sample No. B measured by elemental analysis using XPS is 10 atomic % or less.

From the above, it is found that heat resistance can be improved by optimizing the Si content at the surface.

What is claimed is:

1. An additive manufacturing powder used for producing an additively manufactured body to be formed into a metal sintered body by sintering, the additive manufacturing powder comprising:
a modeling particle containing a metal material; and
a coating film provided at a surface of the modeling particle and containing a compound derived from a coupling agent containing a hydrophobic functional group, wherein
when elemental analysis by X-ray photoelectron spectroscopy (XPS) is performed on the surface of the modeling particle, a Si content is 15 atomic % or more and 40 atomic % or less.

2. The additive manufacturing powder according to claim 1, wherein
the metal material is an Fe-based metal material containing Si.

3. The additive manufacturing powder according to claim 1, wherein
the modeling particle includes
a core portion formed of the metal material, and
a coating portion that coats a surface of the core portion and contains si.

4. The additive manufacturing powder according to claim 3, wherein
the coating portion contains silicon oxide.

5. The additive manufacturing powder according to claim 1, wherein
the hydrophobic functional group is a cyclic structure-containing group, a fluoroalkyl group, or a fluoroaryl group.

6. The additive manufacturing powder according to claim 5, wherein
the additive manufacturing powder has a water contact angle of 80° or more and 150° or less as measured at 25° C. by a θ/2 method in a state of being spread in a layered shape after being subjected to a heat treatment of heating at 200° C. for 72 hours in an ambient atmosphere.

7. The additive manufacturing powder according to claim 1, wherein
when a volume-based particle size distribution is obtained by a laser diffraction type particle size distribution measuring apparatus,
a particle diameter D50 is 1.0 μm or more and 15.0 μm or less, and
a ratio (D90−D10)/D50 is 0.8 or more and 2.7 or less, where
D10 is a particle diameter when a cumulative frequency is 10% from a small diameter side, D50 is a particle diameter when the cumulative frequency is 50% from the small diameter side, and D90 is a particle diameter when the cumulative frequency is 90% from the small diameter side.

8. A method for producing an additive manufacturing powder used for producing an additively manufactured body to be formed into a metal sintered body by sintering, the method comprising:
reacting a coupling agent containing a hydrophobic functional group with a surface of a modeling particle containing a metal material to form a coating film containing a compound derived from the coupling agent, wherein
when elemental analysis by X-ray photoelectron spectroscopy (XPS) is performed on the surface of the modeling particle, a Si content is 15 atomic % or more and 40 atomic % or less.

9. The method for producing an additive manufacturing powder according to claim 8, wherein
the metal material contains Si, and
the method further comprises:
subjecting a metal particle formed of the metal material to a heat treatment to precipitate Si at a surface of the metal particle and obtain the modeling particle.

10. The method for producing an additive manufacturing powder according to claim 8, wherein
the modeling particle includes
a core portion formed of the metal material, and
a coating portion that coats a surface of the core portion and contains Si, and
the method further comprises:
forming the coating portion by an ALD method.

11. An additively manufactured body comprising:
the additive manufacturing powder according to claim 1; and
a binder that binds particles of the additive manufacturing powder.
